(19) United States
(12) Patent Application Publication
(10) Pub. No.: US 2002/0171125 A1
(43) Pub. Date: Nov. 21, 2002

(54) Organic semiconductor devices with short channels

(76) Inventors: Zhenan Bao, Jersey City, NJ (US); John A. Rogers, New Providence, NJ (US); Jan Hendrik Schon, Summit, NJ (US)

Correspondence Address: Docket Administrator, (Room 3J-219), Lucent Technologies Inc., 101 Crawfords Corner Road, Holmdel, NJ, 07733, US

(21) Appl. No.: 09/860,107

(22) Filed: May 17, 2001

(51) Int. Cl. H01L 23/58

(52) U.S. Cl. 257/642

(57) ABSTRACT

A three-terminal device includes first electrode, second electrode, gate electrode and an active channel coupling the first and second electrodes. The active channel has a layer of organic molecules with conjugated multiple bonds. The delocalized π-orbitals associated with the conjugated multiple bonds extend normal to the layer.

### BACKGROUND OF THE INVENTION

1. Field of the Invention

The invention relates to semiconductor devices with active organic channels and three or more terminals.

2. Discussion of the Related Art

Much interest in organic circuits stems from the availability of organic circuits with desirable mechanical properties and the availability of inexpensive fabrication techniques for such organic circuits. Exemplary of the desirable mechanical properties are mechanical flexibility, lightweightness, and ruggedness typically associated with circuits made with plastic substrates. Exemplary of the inexpensive fabrication techniques are reel-to-reel manufacture, solution-based deposition, feature printing, and lamination construction.

Active organic devices have an organic semiconductor channel and three or more electrodes. The active organic semiconductor channel couples two of the electrodes and has a conductivity that is responsive to a voltage applied to a third one of the electrodes. The third one of the electrodes is generally referred to as the gate electrode. Exemplary of active organic devices with three terminals are organic field-effect-transistors (FETs).

Research has targeted improving operating characteristics of organic FETs, because organic FETs usually have characteristics that are much inferior to those of inorganic FETs. Two characteristics that usually have worse values in organic FETs than in an inorganic FETs are the mobility of the active channel and the ON/OFF ratio for the drain current. These two characteristics are typically smaller by at least an order of magnitude in organic FETs.

If these two characteristics had values closer to those of inorganic FETs, several problems arising in circuits based on organic FETs would disappear. To this end, the desirable mechanical properties and cost savings associated with many organic devices could stimulate greater use of organic circuits if active organic devices had operating characteristics closer to those of active inorganic devices.

### SUMMARY OF THE INVENTION

Various active organic devices embodying principles of the inventions have active organic channels that are shorter than those of conventional active organic devices. The channel lengths are one or, at most, a few times the lengths of the organic molecules in the channels. Long axes of the organic molecules in the channels may be along the conduction direction rather than perpendicular to that direction as in conventional organic FETs. The short lengths of the active channels and/or alignments of the molecules therein cause the mobilities and/or ON/OFF drain current ratios of these embodiments of organic FETs to have values that are about as large as those of silicon-based FETs.

Another active organic device embodying principles of the inventions has an active organic channel that includes a layer of organic molecules with conjugated multiple bonds. The delocalized π-orbitals associated with the conjugated multiple bonds extend normal to the layer.

Another active organic device embodying principles of the inventions has an active organic channel that includes organic molecules. A portion of the organic molecules are chemically bonded to at least one electrode of the device.

Another embodiment according to principles of the inventions features a process for constructing an organic transistor. The process includes providing a source or drain electrode and forming a layer of organic molecules on the source or drain electrode. After forming the electrode and layer, the process includes forming the remaining of the source and drain electrodes on a free surface of the layer.

### BRIEF DESCRIPTION OF THE DRAWINGS

FIG. 1 is a cross-sectional view of an organic field-effect-transistor (OFET) having a step topology and embodying principles of the inventions;

FIG. 2 is a magnified cross-sectional view of the active channel of one OFET of the type shown in FIG. 1;

FIG. 3 shows exemplary molecules for active channels of OFETs of the type shown in FIG. 1;

FIG. 4 shows drain-current/drain-voltage characteristics of the OFET shown in FIG. 2;

FIG. 5 shows how the drain current of the same OFET depends on gate voltage;

FIG. 6 shows how the dependence of the drain current on gate voltage varies with temperature for the same OFET;

FIG. 7 is a flow chart illustrating a process embodying principles of the inventions for fabricating an active channel of an OFET;

FIG. 8 is a flow chart illustrating a process embodying principles of the inventions for fabricating an OFET of the type shown in FIGS. 1 and 2;

FIG. 9 shows an inverter circuit with OFETs of type shown in FIGS. 1 and 2;

FIG. 10 shows the voltage gain characteristic of the inverter circuit of FIG. 9;

FIG. 11 is a cross-sectional view of an OFET having a flat topology and embodying principles of the inventions;

FIG. 12 shows organic molecules for active channels of n-type embodiments of the OFET of FIG. 11;

FIG. 13 shows organic molecules for active channels of p-type embodiments of the OFET of FIG. 11;

FIGS. 14-15 show drain-current/drain-voltage characteristics of an OFET with an active channel of 4,4′-biphenyldithiol and the topology of FIG. 11;

FIG. 16 is a cross-sectional view of an OFET having a vertical topology and embodying principles of the inventions;

FIG. 17 is a flow chart for a fabrication process for the OFET of FIG. 16 according to principles of the inventions; and

FIG. 18 is a cross-sectional view of a structure of the OFET of FIG. 17 produced by lamination.

### DETAILED DESCRIPTION OF THE EMBODIMENTS

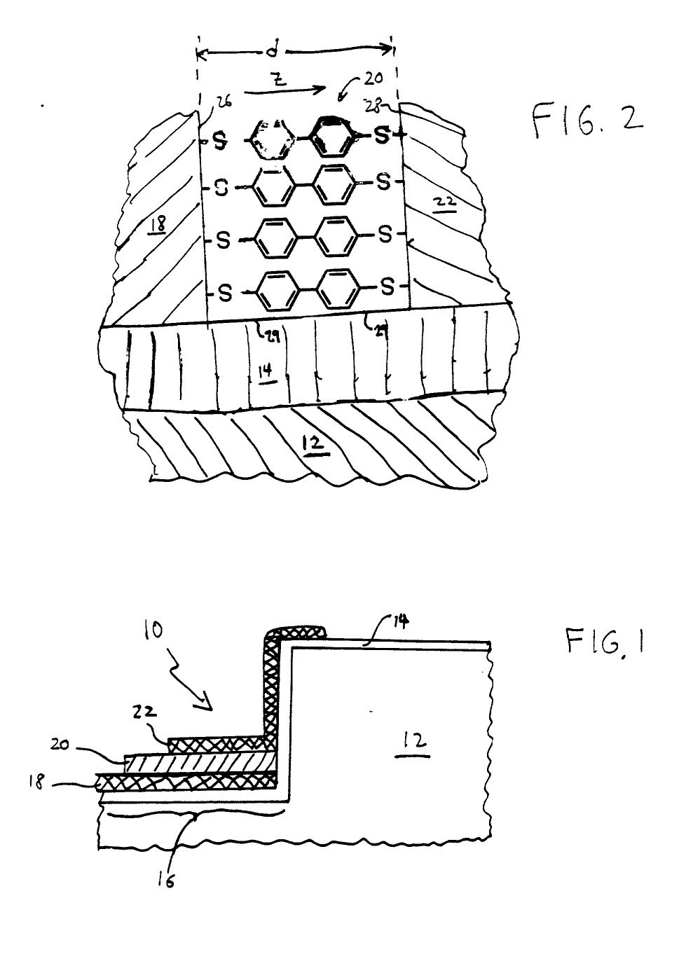

FIG. 1 shows an organic field-effect-transistor (OFET) 10 that forms a step-like structure on a conductive substrate 12. The step-like structure includes a dielectric layer 14 that covers a step on the substrate 12. The substrate 12 and dielectric layer 14 form a gate structure for the OFET 10. Exemplary substrates 12 include organic and inorganic conductors, e.g., a metal or heavily doped silicon that acts like a conductor. Exemplary dielectric layers 14 include inorganic and organic layers, e.g., layers of SiO₂ or SiO₂ (CH₂)_{N}CO₂.

The step-like structure includes a horizontal region 16 covered by a stack-like channel structure. From the horizontal region 16 out, the stack-order of the channel-structure is dielectric layer 14, gold source electrode 18, active channel layer 20, and gold drain electrode 22. The active channel layer 20 includes one or more layers of aligned organic molecules that are aligned. The conductivity of the active channel layer 20 responds to voltages applied to adjacent gate electrode 22 in a manner similar to that of conduction channels of conventional FETs (not shown).

FIG. 2 provides a magnified view of channel layer 20 of OFET 10 shown in FIG. 1. The channel layer 20 is a self-assembled mono-layer of organic molecules in which long molecular axes are aligned along direction “z”, which is normal to the surface of the channel layer 20 and along the channel's conduction direction. The molecules have conjugated multiple bonds whose π-orbitals form delocalized clouds that extend normal to the channel layer 20. The molecular π-orbital clouds form conduction paths that substantially bridge the gap between adjacent surfaces 26, 28 of the source and drain electrodes 18, 22. In channel layer 20, molecular alignments encourage intra-molecular conduction through conjugated multiple bonds rather than inter-molecular conduction through overlaps between π-orbitals of adjacent molecules as in conventional OFETS. The molecules of the channel layer 20 molecularly bind to adjacent metallic surfaces 26, 28 by sulfide bonds. The active channel of transistor 10 has a short length, d, i.e., less than 30 nanometers (nm), because the channel is a mono-layer whose width is one molecular length. Typical channel lengths, d, have values from about 1 nm to about 3 nm for self-assembled mono-layers.

The channel layer 20 includes a thin region adjacent an interface 29 with gate dielectric layer 14. The region is several molecules thick and provides the channel with a current conductivity that is responsive to voltages applied to substrate 12, i.e., to the gate electrode.

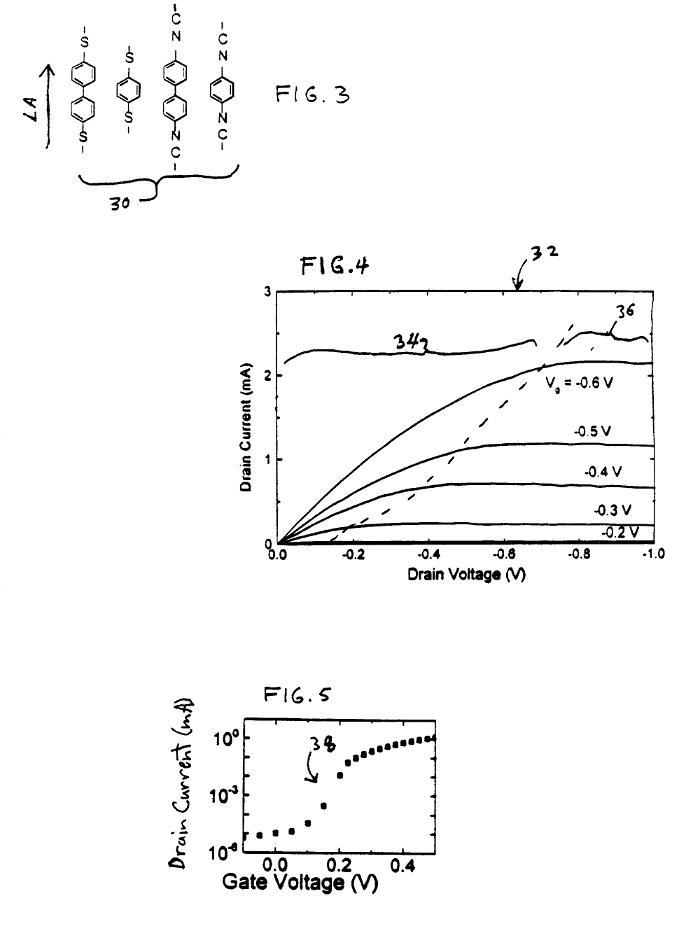

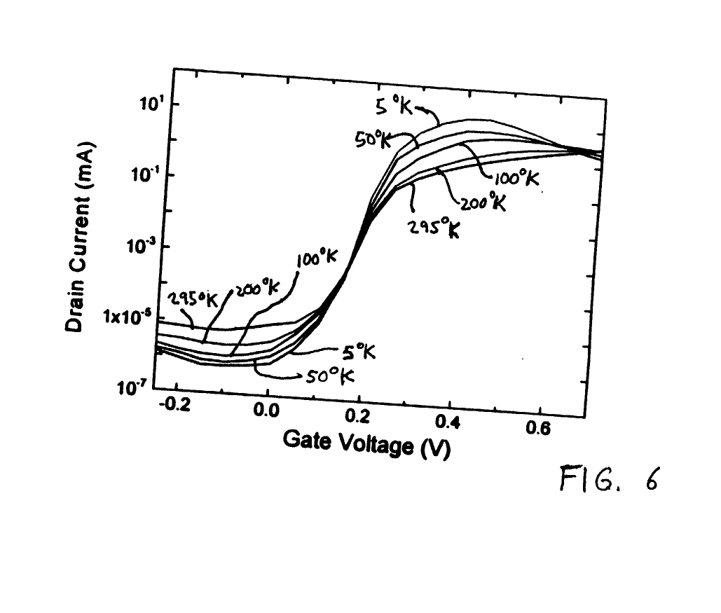

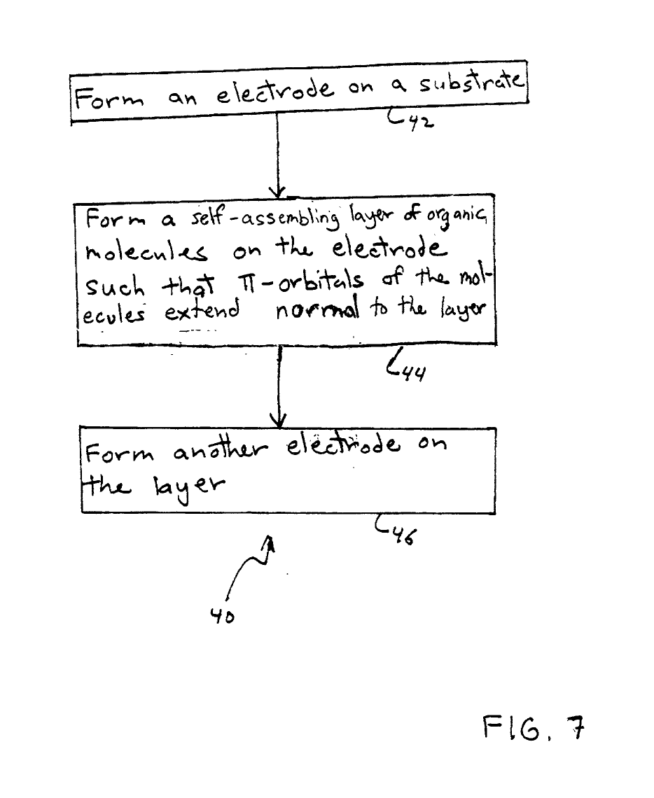

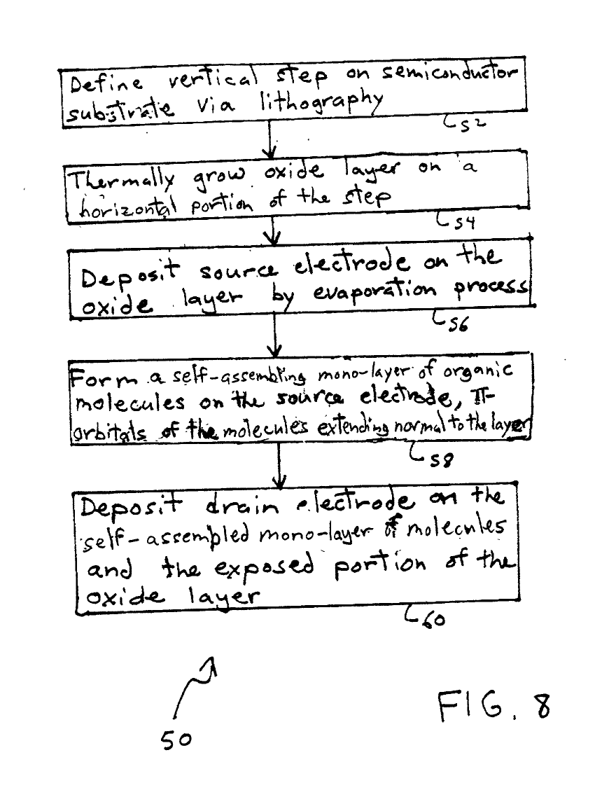

FIG. 3 shows several types of molecules 30 with conjugated multiple bonds that are used in active channels of OFETs 10 with the topology shown in FIG. 1. In the active channels, the molecules 30 are arranged in a mono-layer. In the mono-layer, the direction, LA, of long axes of the molecules 30 is aligned along channel conduction direction, z, as shown in FIG. 2. Thus, these embodiments of OFET 10 have short channels whose lengths, d, are fixed by lengths of the molecules 30 forming the channels. Exemplary values of channel length, d, are less than 30 nm and preferably less than about 15 nm.

Other embodiments of OFET 10 have active channels with two or more layers of molecules with conjugated multiple bonds (not shown). Active channel lengths remain less than 30 nm and preferably less than about 15 nm. The active channel lengths are preferably less than or equal to three molecular lengths.

FIG. 4 shows drain-current/drain-voltage characteristics 32 for transistor 10 of FIG. 2 at room temperature. The characteristics 32 have both ohmic and saturation regions 34, 36 that indicate typical FET behavior. The characteristics 32 also depend on the gate voltage in a manner indicative of a p-type FET.

FIG. 5 provides data 38 showing how the channel current of OFET 10, shown in FIG. 2, depends on gate-voltage in the ohmic region at room temperature. The data 38 indicates that OFET 10 has p-type conductivity. The channel current changes by a factor of about 10⁵ if the gate voltage is changed by 0.4 volts (V).

The measured characteristics of OFET 10 of FIG. 1 correspond to a mobility of about 250-300 cm²/Volt-second at room temperature. These large mobility values are approximately equal to mobility values available through hole motion in silicon FETs.

FIG. 6 shows the temperature dependence of the channel current response to gate voltage for the same embodiment of OFET 10.

FIG. 7 is a flow chart of a fabrication process 40 for the channel portion of OFET 10 shown in FIG. 1. The fabrication process 40 includes depositing a metallic electrode, i.e., source or drain electrode 18, 22, on a substrate (step 42). The deposition includes evaporating gold to produce the deposition. After forming the electrode, the process 40 includes forming a self-assembling mono-layer of organic molecules, e.g., layer 20, with conjugated multiple bonds on the deposited electrode, e.g., by a solution-based process (step 44). The molecules of the mono-layer have long molecular axes directed normal to the surface of the mono-layer so that delocalized π-orbitals extend normal to the mono-layer substantially cross the mono-layer. The molecules of the mono-layer also have terminal reactive groups that form linkages with the electrode thereby stabilizing the mono-layer. On the formed mono-layer, the process 40 includes forming another metallic electrode, e.g., the remaining source or drain electrode 18, 22 (step 46). The formation of the remaining electrode includes cooling the formed mono-layer so that the newly deposited metal atoms do not disrupt the arrangement of the molecules in the mono-layer.

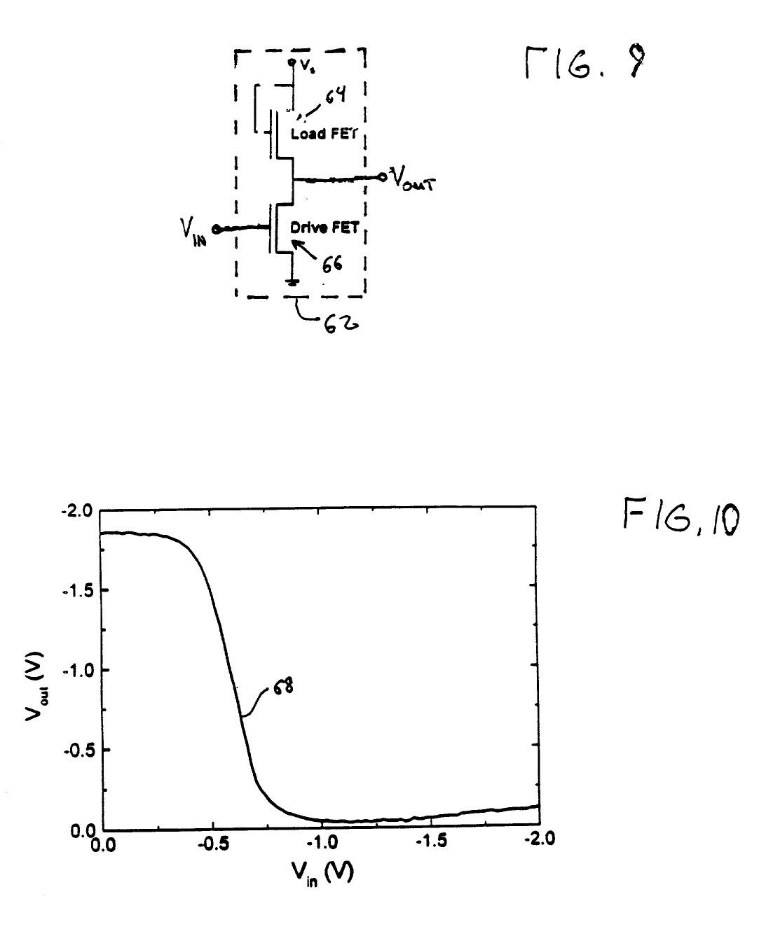

FIG. 8 is a flow chart showing a fabrication process 50 for OFET 10 of FIG. 1. A standard lithography forms a vertical step on a surface of substrate 12, e.g., a doped silicon substrate (step 52). On the step, the process 50 includes thermally growing an oxide layer, e.g., about 30 nm of SiO₂, to produce gate dielectric layer 14 (step 54). The process 50 includes depositing a gold source electrode 18 on a portion of the gate dielectric layer 14 that covers a horizontal region 16 of the step (step 56). The electrode deposition involves a thermal evaporation of gold. On the source electrode 18, the process 50 includes forming a self-assembling mono-layer 20 of molecules (step 58). The molecules of the mono-layer 20 have delocalized π-orbitals that extend normal to and substantially cross the mono-layer 20 and have terminal thiol or isocyanide end groups that bond to the gold source electrode 18 to stabilize the mono-layer. While cooling the structure, the process 50 includes forming drain electrode 22 by a shallow angle evaporation of gold onto the mono-layer 20 (step 60). Again, terminal thiol or isocyanide groups on the molecules of the mono-layer 20 bond with the gold drain electrode 22 to stabilize the final channel-structure itself.

The OFETs 10 of FIGS. 1-2 are useful in a variety of circuits and devices.

FIG. 9 shows an inverter 62 using two OFETs 64, 66 of the topology shown in FIGS. 1 and 2. The two OFETs 64, 66 have active channel layers 20 of 4,4′-biphenyldithiol. The OFETs 64, 66 are serially connected between power voltage, Vₛ, and ground. The OFET 64 has source and gate electrodes shorted and thus, functions as a load. The gate electrode of the OFET 66 functions as an input of the inverter 62 and the source electrode of the OFET 66 functions as an output of the inverter 62.

FIG. 10 shows a gain characteristic 68 for inverter 62, shown in FIG. 9. The inverter 62 has a channel-off state in which output voltage, Vₒᵤₜ, is approximately −2 volts, i.e., Vₛ, and a channel-on state in which Vₒᵤₜ is approximately 0 volts, i.e., the ground voltage. In the channel-on state, the value of Vₒᵤₜ corresponds to a voltage gain of about 6.

In exemplary digital logic circuits, the inverter 62 functions as a building block. In such circuits, the output voltages Vₒᵤₜ=−2 and Vₒᵤₜ=0 are voltage values that represent logic 1 and logic 0, respectively.

Other topologies exist for OFETs with short organic active channels.

FIG. 11 shows a thin-film topology for an organic FET 80. The FET 80 includes a flat conductive substrate 82, e.g., heavily doped silicon or an organic conductor, which functions as a gate electrode. A gate dielectric layer 84 covers the flat surface of the substrate 82. Exemplary dielectrics include oxides, organic dielectrics, and organic dielectrics that self-assemble into mono-layers. On the surface of the gate dielectric layer 84 rest source and drain electrodes 86, 88. The gate dielectric layer 84 insulates the electrodes 86, 88 from the substrate 82. The source and drain electrodes 86, 88 are separated by a channel 90. The channel 90 is formed of a mono-layer of organic molecules with conjugated double bonds.

The mono-layer 90 has an organized structure that fixes molecules therein to have long axes directed normal to the mono-layer 90 so that delocalized π-orbitals also extend normal to the mono-layer 90. Terminal sulfide or cyanide groups on molecules stabilize the mono-layer 90 and orientations of the molecules therein. The terminal groups bond to the source and drain electrodes 86, 88.

Various embodiments of channels 90 use different molecules to produce n-type or p-type behavior in OFET 80. FIG. 12 shows molecules 92 for use in the channel 90, e.g., typically to produce n-type behavior in the FET 80. FIG. 13 shows molecules 94 for use in the channel 90, e.g., typically to produce p-type behavior in the FET 80. FIGS. 12 and 13 also indicate direction, L, of long axes of the molecules 92, 94.

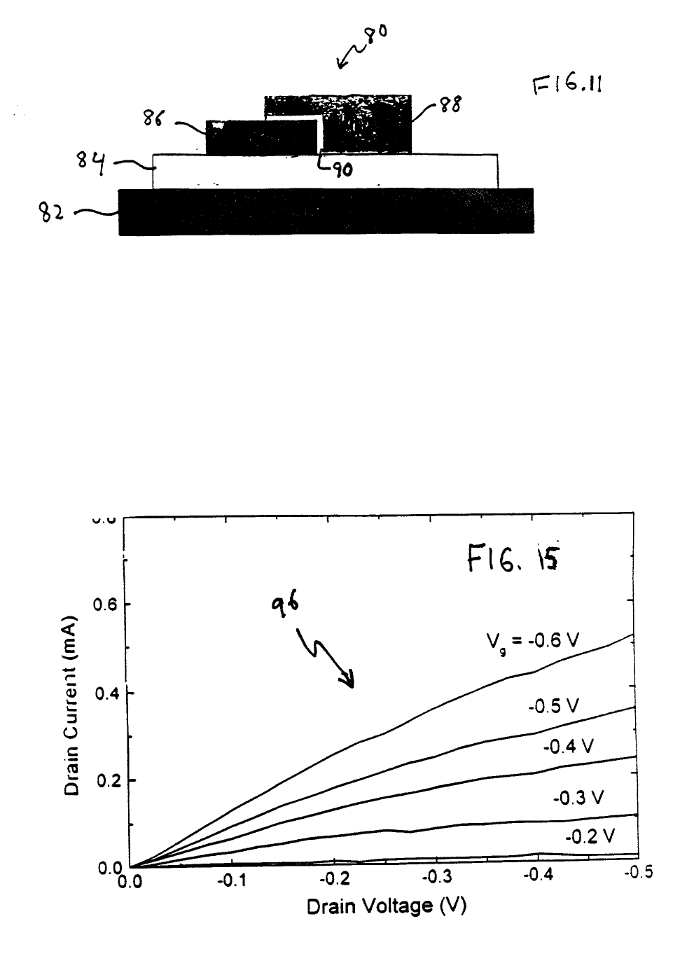

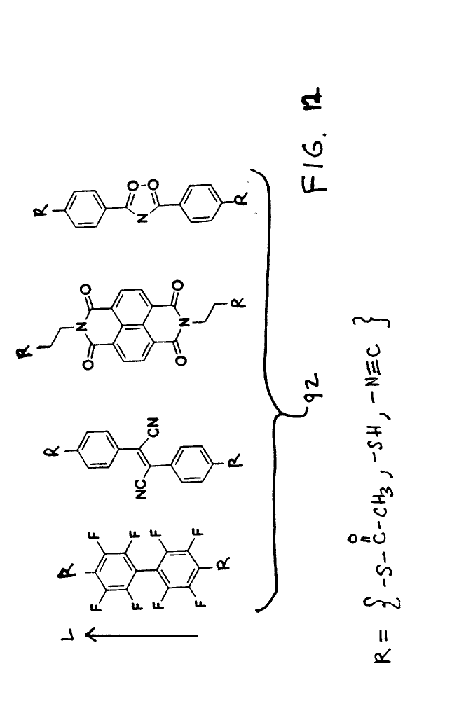

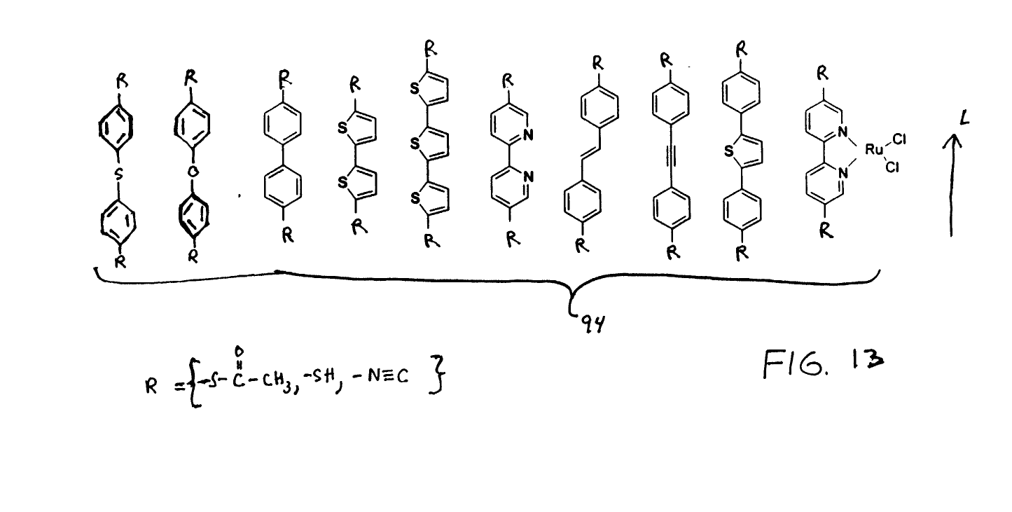

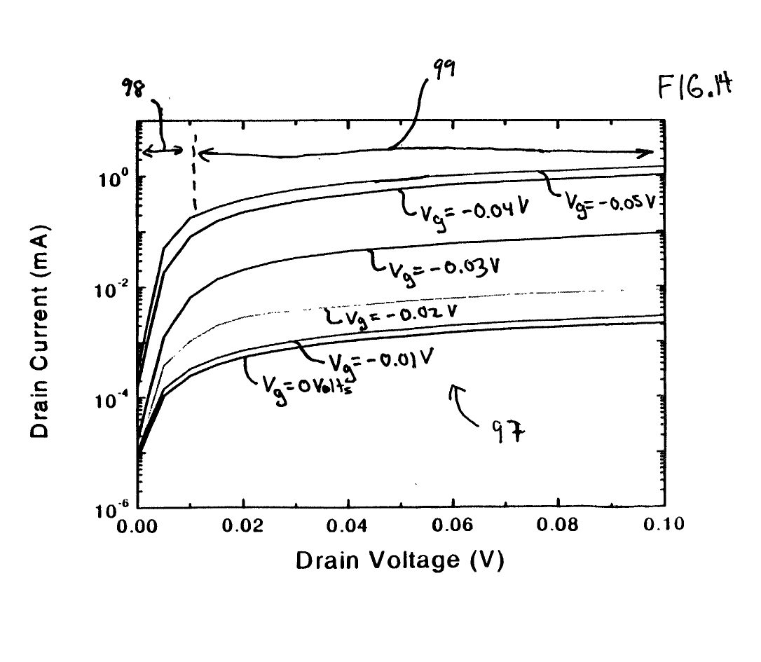

FIGS. 14-15 show drain-current/drain-voltage characteristics 96, 97 of an exemplary OFET 80 with the topology shown in FIG. 11 and a channel 90 formed of 4,4′-biphenyldithiol. The characteristics 96, 97 are responsive to negative gate voltages in a manner that is typical of FETs. The characteristics 97 exhibit ohmic and saturation regions 98, 99. The OFET 80 has characteristics typical of FETs.

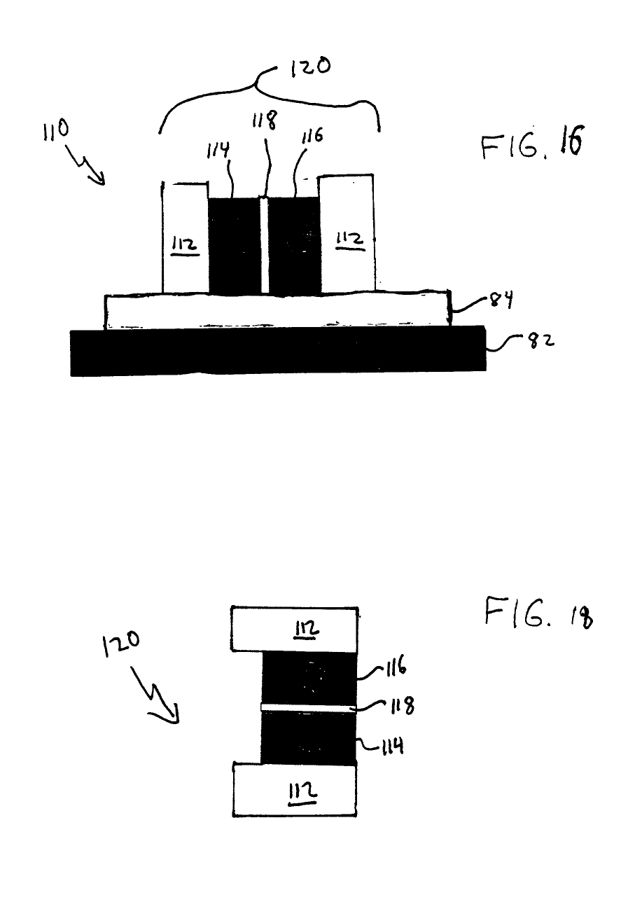

FIG. 16 is a cross-sectional view of an OFET 110 with a vertical topology. The OFET 110 includes semiconductor substrate 82 and dielectric layer 84 that function as a gate structure. The gate structure supports a vertical channel structure 120. The vertical channel structure 120 includes dielectric side supports 112, a gold source electrode 114, a gold drain electrode 116, and a self-assembled layer 118 of organic molecules. The side supports are dielectrics, e.g., plastics. The molecules of layer 118 have conjugated double bonds and are arranged to have long axes transverse to adjacent surfaces of the electrodes 114, 116 so that molecular π-orbitals extend perpendicular to the layer 118.

One OFET 110 constructs gate dielectric layer 84 from a self-assembled mono-layer of organic molecules and side supports 112 from silicone elastomer. Due to the compositions of the gate dielectric layer 84 and side supports 112, pushing vertical channel structure 120 onto the surface of the gate dielectric layer 84 causes the side supports 112 to physically bind to the gate dielectric layer 84.

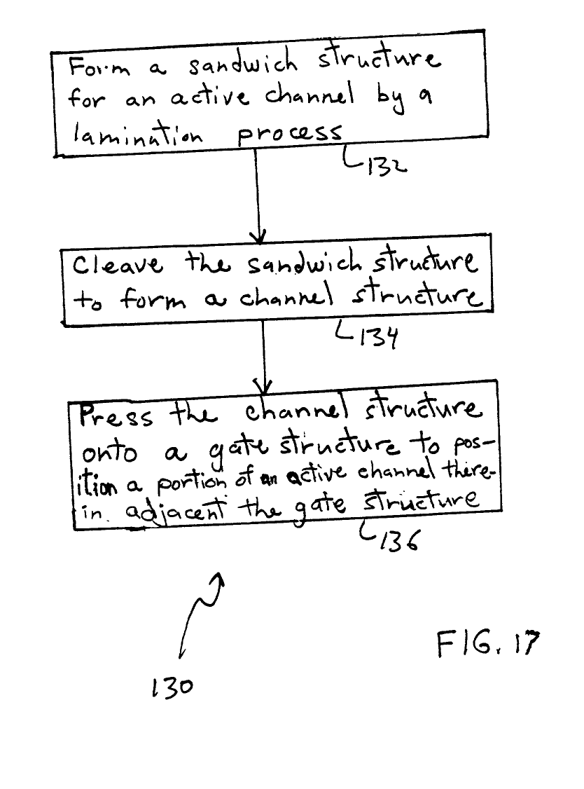

FIG. 17 is a flow chart for a lamination-based process 130 for fabricating OFET 110 of FIG. 16. The process 130 includes making a sandwich structure by a lamination process (step 132). The lamination process includes forming two multi-layered sheets by evaporation deposition of gold on thin sheets of silicon rubber. On one of the sheets, a mono-layer of molecules with conjugated multiple bonds is deposited. The molecules have terminal thiol or isocyanide groups that bind with the deposited gold to stabilize the mono-layer. To form the sandwich structure, the two sheets are laminated so that the mono-layer is adjacent the two layers of gold. The terminal thiol or isocyanide groups on the molecules of the mono-layer bind to the second layer of gold thereby holding the sandwich structure together. The process 130 includes cleaving the sandwich structure to form the channel structure 120, shown in FIG. 19 (step 134). Then, the channel structure 120 is pressed vertically onto the dielectric layer 84 to form a conformal contact between the channel structure 120 and gate dielectric layer 84. If the gate dielectric layer 84 is made of silicone rubber, pressing the channel structure 120 into the gate dielectric layer 84 fixes physical relations between the structure 120 and layer 84. Otherwise, a layer (not shown) is deposited on the OFET 110 to permanently fix the physical relationships between the channel structure 120 and gate structure 82, 84.

In other embodiments, the multi-terminal devices 10, 80, 120 of FIGS. 1, 11, and 16 include four or more electrodes. Fore example, some embodiments have two or more gate electrodes to control different portions of the active channel.

Other embodiments will be apparent to those skilled in the art from the specification, drawings, and claims.

What we claim is1:

1. An apparatus comprising:
a first electrode;
a second electrode;
a third electrode; and
an active channel located between the second and third electrodes, the active channel having a layer of organic molecules with conjugated multiple bonds and delocalized π-orbitals that extend normal to the layer, the active channel having a conductivity that depends on a voltage applied to the first electrode.

2. The apparatus of claim 1, wherein the layer is a mono-layer.

3. The apparatus of claim 1, further comprising:
a fourth electrode, the active channel having a conductivity responsive to a voltage applied to the fourth electrode.

4. The apparatus of claim 2, wherein one of the first and second electrodes is metallic and the molecules include a group molecularly bound to the metallic one of the first and second electrodes.

5. The apparatus of claim 1, wherein the channel has a mobility of at least 5 cm²/volt-second.

6. The apparatus of claim 1, wherein the apparatus is a field effect transistor.

7. An organic transistor comprising:
a drain electrode;
a source electrode; and
an active channel of organic molecules located between the source and drain, the active channel having a length that is shorter than three times a length of one of the organic molecules.

8. The transistor of claim 7, further comprising:
a layer of insulator located adjacent an edge of the active channel; and
a gate located adjacent the layer and being capable of applying a voltage that changes a conductivity of the active channel.

9. The transistor of claim 7, wherein the length of the active channel is less than twice a length of one of the organic molecules.

10. The transistor of claim 7, wherein the organic molecules have long axes oriented normal to an adjacent surface of one of the source electrode and the drain electrode.

11. The transistor of claim 7, wherein the molecules have conjugated multiple bonds along long axes thereof.

12. The transistor of claim 10, wherein the channel conducts currents along the long axes of the organic molecules.

13. The transistor of claim 7, wherein the organic molecules bind to one of the source electrode and the drain electrode.

14. The transistor of claim 7, wherein the channel has a mobility of at least 5 cm²/volt-second.

15. An organic transistor comprising:
a drain electrode;
a source electrode; and
an active channel of organic molecules located between the source and drain electrodes, the active channel having a length shorter than about 30 nanometers.

16. The transistor of claim 15, further comprising:
a layer of insulator located adjacent an edge of the active channel; and
a gate located adjacent the layer and being capable of changing a conductivity of the active channel.

17. The transistor of claim 16, wherein the length of the active channel is less than about 15 nanometers.

18. The transistor of claim 16, wherein the organic molecules have long axes oriented normal to an adjacent surface of the source electrode or the drain electrode.

19. The transistor of claim 16, wherein the molecules have conjugated multiple bonds along their long axes.

20. The transistor of claim 16, wherein the channel conducts currents along the long axes of the organic molecules.

21. The transistor of claim 15, wherein the channel has a mobility of at least 5 cm²/volt-second.

22. An active organic device comprising:
a first electrode;
a second electrode; and
an active channel of organic molecules located between the first and second electrodes, a portion of the molecules being chemically bonded to at least one of the first and second electrodes.

23. The device of claim 22, further comprising:
a layer of insulator being located adjacent an edge of the active channel; and
a gate electrode being located adjacent the layer and being capable of changing a conductivity of the active channel.

24. The device of claim 23, wherein the organic molecules have conjugated multiple bonds along axes oriented normal to an adjacent surface of one of the first and second electrodes.

25. The device of claim 24, wherein the channel conducts currents along the long axes of the organic molecules.

26. The device of claim 23, wherein the channel is a mono-layer of the molecules.

27. The device of claim 24, wherein the molecules are chemically bonded to the one of the first and second electrodes by one of sulfur atoms and isocyanide groups.

28. The device of claim 23, wherein the channel has a mobility of at least 5 cm²/volt-second.

29. An organic transistor comprising:
a drain electrode;
a source electrode; and
an active channel of organic molecules located between the source and drain electrodes, the molecules having long molecular axes oriented normal to adjacent surfaces of the electrodes.

30. The transistor of claim 29, further comprising:
a layer of insulator being located adjacent an edge of the active channel; and
a gate being located adjacent the layer and being capable of changing a conductivity of the active channel.

31. The transistor of claim 30, wherein the molecules have conjugated multiple bonds along their long axes.

32. The transistor of claim 30, wherein the channel conducts currents along the long axes of the organic molecules.

33. The transistor of claim 29, wherein the channel has a mobility of at least 5 cm²/volt-second.

34. A process for constructing an organic transistor, comprising:
providing one of a source electrode and a drain electrode;
forming a layer of organic molecules on the one of a source electrode and a drain electrode; and
then, providing the other of a source electrode and a drain electrode on a free surface of the layer.

35. The process of claim 34, wherein the layer is a mono-layer.

36. The process of claim 34, wherein the forming positions long axes of the molecules normal to a surface of the one of a source electrode and a drain electrode.

37. The process of claim 34, further comprising:
the providing the other of a source and a drain electrode includes cooling the formed layer.

38. The process of claim 34, wherein the acts of providing produce a metallic source electrode and a metallic drain electrode.

39. The process of claim 34, wherein the act of providing the other of a source electrode and a drain electrode includes laminating two sheets.

40. An apparatus comprising:
a first electrode;
a second electrode;
a gate electrode; and
an active channel located between the first and second electrodes, the channel including organic molecules, having a length, and having a conductivity dependant on a voltage applied to the gate electrode; and
wherein the channel length or orientation of the organic molecules cause the channel to have a mobility of at least 5 cm²/volt-second.

41. The apparatus of claim 40, wherein the layer is a mono-layer of the molecules.

42. The apparatus of claim 40, wherein one of the first and second electrodes is metallic and the molecules include a group molecularly bound to the metallic one of the first and second electrodes
